(19) United States
(12) Patent Application Publication
(10) Pub. No.: US 2008/0277682 A1
(43) Pub. Date: Nov. 13, 2008

(54) DUAL SURFACE-ROUGHENED N-FACE HIGH-BRIGHTNESS LED

(75) Inventors: Umesh K. Mishra, Montecito, CA (US); Michael Grundmann, Goleta, CA (US); Steven P. DenBaars, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/059,918

(22) Filed: Mar. 31, 2008

Related U.S. Application Data
(60) Provisional application No. 60/908,919, filed on Mar. 29, 2007.

(51) Int. Cl. H01L 33/00; H01L 21/00

(52) U.S. Cl. 257/98; 438/29; 257/E33.001; 257/E21.001

(57) ABSTRACT

A light emitting diode, comprising a substrate, a buffer layer on the substrate, an active layer on the buffer layer and between an n-type layer and a p-type layer, a tunnel junction adjacent the p-type layer, and n-type contacts to the tunnel junction and the n-type layer, wherein the buffer layer, n-type layer, p-type layer, active region and tunnel junction comprise III-nitride material grown in a nitrogen-face (N-face) orientation. The substrate surface upon which the III-nitride material is deposited is patterned to provide embedded backside roughening. A top surface of the tunnel junction, which also the top surface of the III-nitride material, is roughened.

### CROSS-REFERENCE TO RELATED APPLICATIONS

This application claims the benefit under 35 U.S.C. Section 119(e) of the following co-pending and commonly-assigned U.S. patent applications:

U.S. Provisional Application Ser. No. 60/908,919 filed on Mar. 29, 2007, by Umesh K. Mishra, Michael Grundmann, Steven P. DenBaars, and Shuji Nakamura, entitled “DUAL SURFACE-ROUGHENED N-FACE HIGH-BRIGHTNESS LED” attorneys' docket number 30794.217-US-P1 (2007-279-1);

which application is incorporated by reference herein.

This application is related to the following co-pending and commonly-assigned applications:

U.S. Utility patent application Ser. No. 11/768,105, filed Jun. 25, 2007, by Michael Grundmann and Umesh K. Mishra, entitled “POLARIZATION INDUCED TUNNEL JUNCTION”, attorney's docket number 30794.186-US-U1 (2007-668), which application claims priority under Section 119(e) of U.S. Provisional Patent Application Ser. No. 60/815,944, filed on Jun. 23, 2006, by Michael Grundmann and Umesh K. Mishra, entitled “POLARIZATION INDUCED TUNNEL JUNCTION”, attorney's docket number 30794.186-US-P1 (2007-668);

U.S. Utility patent application Ser. No. 11/855,591, filed Sep. 14, 2007, by Stacia Keller, Umesh K. Mishra and Nicholas A. Fichtenbaum, entitled “METHOD FOR HETEROEPITAXIAL GROWTH OF HIGH-QUALITY N-FACE GaN, InN, AND AlN AND THEIR ALLOYS BY METAL ORGANIC CHEMICAL VAPOR DEPOSITION”, attorney's docket number 30794.207-US-U1 (2007-121), which application claims priority under Section 119(e) of U.S. Provisional Application Ser. No. 60/866,035 filed on Nov. 15, 2006, by Stacia Keller, Umesh K. Mishra and Nicholas A. Fichtenbaum, entitled “METHOD FOR HETEROEPITAXIAL GROWTH OF HIGH-QUALITY N-FACE GaN, InN, AND AlN AND THEIR ALLOYS BY METAL ORGANIC CHEMICAL VAPOR DEPOSITION,” attorneys' docket number 30794.207-US-P1 (2007-121-1);

U.S. Utility patent application Ser. No. 11/940,856, filed Nov. 15, 2007, by Nicholas A. Fichtenbaum, Umesh K. Mishra and Stacia Keller, entitled “LIGHT EMITTING DIODE AND LASER DIODE USING N-FACE GaN, InN, and AlN AND THEIR ALLOYS”, attorney's docket number 30794.208-US-U1 (2007-204), which application claims priority under Section 119(e) of U.S. Provisional Application Ser. No. 60/866,019 filed on Nov. 15, 2006, by Nicholas A. Fichtenbaum, Umesh K. Mishra and Stacia Keller, entitled “LIGHT EMITTING DIODE AND LASER DIODE USING N-FACE GaN, InN, and AlN AND THEIR ALLOYS” attorneys' docket number 30794.208-US-P1 (2007-204-1);

U.S. Utility patent application Ser. No. xx/xxx,xxx, filed on same date herewith, by Umesh K. Mishra, Yi Pei, Siddharth Rajan, and Man Hoi Wong, entitled “N-FACE HIGH ELECTRON MOBILITY TRANSISTORS WITH LOW BUFFER LEAKAGE AND LOW PARASITIC RESISTANCE”, attorney's docket number 30794.215-US-U1 (2007-269), which application claims priority under Section 119(e) of U.S. Provisional Patent Application Ser. No. 60/908,914, filed on Mar. 29, 2007, by Umesh K. Mishra, Yi Pei, Siddharth Rajan, and Man Hoi Wong, entitled “N-FACE HIGH ELECTRON MOBILITY TRANSISTORS WITH LOW BUFFER LEAKAGE AND LOW PARASITIC RESISTANCE,” attorneys docket number 30794.215-US-P1 (2007-269); and

U.S. Utility patent application Ser. No. xx/xxx,xxx, filed on same date herewith, by Umesh K. Mishra, Lee S. McCarthy, Chang Soo Suh and Siddharth Rajan, entitled “METHOD TO FABRICATE III-N SEMICONDUCTOR DEVICES ON THE N-FACE OF LAYERS WHICH ARE GROWN IN THE III-FACE DIRECTION USING WAFER BONDING AND SUBSTRATE REMOVAL”, attorney's docket number 30794.216-US-U1 (2007-336), which application claims priority under Section 119(e) of U.S. Provisional Patent Application Ser. No. 60/908,917, filed on Mar. 29, 2007, by Umesh K. Mishra, Lee S. McCarthy, Chang Soo Suh and Siddharth Rajan, entitled “METHOD TO FABRICATE III-N SEMICONDUCTOR DEVICES ON THE N-FACE OF LAYERS WHICH ARE GROWN IN THE III-FACE DIRECTION USING WAFER BONDING AND SUBSTRATE REMOVAL,” attorneys docket number 30794.216-US-P1 (2007-336);

which applications are incorporated by reference herein.

### STATEMENT REGARDING FEDERALLY SPONSORED RESEARCH AND DEVELOPMENT

This invention was made with Government support under Grant No. N00014-05-1-0419 (ONR MINE MURI). The Government has certain rights in this invention.

### BACKGROUND OF THE INVENTION

1. Field of the Invention

The present invention is related to a method to produce a light emitting diode (LED) with high extraction efficiency.

2. Description of the Related Art

Prior to this invention, high-brightness LEDs used a thick reflecting p-type contact in a flip-chip configuration with a roughened backside to enhance extraction of light from the wafer.

### SUMMARY OF THE INVENTION

The present invention discloses an optoelectronic device, comprising a p-type layer on an n-type layer, a first n-type contact for the p-type layer, one or more intermediate layers between the first n-type contact and the p-type layer for transferring the device's drive current between the p-type layer and the first n-type contact, and a second n-type contact for the n-type layer. The device may have all n-type contacts and no p-type contacts.

The optoelectronic device may be an LED with a roughened n-type surface terminates the LED to enhance light extraction, wherein the LED's power is supplied via the first n-type contact and the second n-type contact. The LED may have a roughened back-side or may be fabricated on a patterned substrate to provide embedded backside roughening.

The LED may be III-nitride based and the roughened n-type surface may be a roughened nitrogen-face (N-face). The LED may be an epitaxial growth having an N-face orientation.

The intermediate layers may comprise a polarization-induced tunnel junction between the p-type layer and the n-type contact which enables efficient tunneling transport between the p-type layer and the n-type contact and one or more n-type conductive layers between the polarization induced tunnel junction and the n-type contact. The one or more n-type conductive layers may be an n-type current spreading layer to compensate for minimal electrical contact created by the roughening. The polarization-induced tunnel junction may be aluminum nitride, and the n-type conductive layer and p-type layer are gallium nitride.

The present invention also discloses an optoelectronic device comprising one or more intermediate layers for connecting an n-type contact and a p-type region of the optoelectronic device, wherein the intermediate layers transfer sufficient charge to power light emission from the optoelectronic device. The intermediate layers may create a depletion region at a junction between the n-type contact and the p-type region, and the depletion region is sufficiently small as to enable tunneling transport between the n-type contact and the p-type region. The intermediate layers may comprise an n-type layer on a polarization-induced tunnel junction.

The present invention also discloses a method for fabricating an optoelectronic device, comprising fabricating only n-type contacts to the device; and roughening a top surface of the device, which is an n-type surface, and a bottom surface of the device.

The present invention also discloses an AlInGaN-based optoelectronic device, comprising a roughened N-face surface, and a surface opposite the roughened N-face surface that is also roughened, wherein the roughened surfaces enhance light extraction from the device.

### BRIEF DESCRIPTION OF THE DRAWINGS

Referring now to the drawings in which like reference numbers represent corresponding parts throughout:

FIG. 1 is a schematic diagram of N-face LED with a patterned sapphire substrate (PSS) and surface roughening.

FIG. 2 is a simulated band diagram and schematic of the epitaxial structure of an N-face LED with tunnel junction at at the top for contacts, wherein the tunnel junction is formed by the thin aluminum nitride (AlN) layer.

### DETAILED DESCRIPTION OF THE INVENTION

In the following description of the preferred embodiment, reference is made to the accompanying drawings that form a part hereof, and in which is shown by way of illustration a specific embodiment in which the invention may be practiced. It is to be understood that other embodiments may be utilized and structural changes may be made without departing from the scope of the present invention.

Technical Description

The proposed devices of the present invention use back-side roughening in conjunction with top-side roughening to enhance light extraction, and use highly conductive contact layers to reduce the contact size to a minimum, thereby further increasing extraction through the top-side. (In this description, top-side refers to the terminating surface of the epitaxial growth, while back-side refers to the back of the substrate opposite the side where growth is performed or the surface of a layer that interfaces to the substrate.)

These devices are grown on the N-face of aluminum indium gallium nitride (AlInGaN), with nitrogen terminating the surface, as opposed to the standard growth on the metal-face of these alloys. N-face gallium nitride (GaN) is less chemically stable than gallium face (Ga-face) GaN, so it is possible to use a wet etch, such as potassium hydroxide (KOH), to etch a random array of facets into a N-face GaN layer. These facets provide more surface area than a planar surface and the roughness effectively scatters light out of the LED from the top of the device.

Back-side roughening can be accomplished by using a patterned sapphire substrate (PSS), which is a substrate in which a pattern has been transferred using lithography and etching, and on which (AlIn)GaN is grown. This may also be accomplished using any etch that produces facets on the sapphire substrate, as long as the epitaxial film has orientation control. Similar to top-side roughening, the back side with a PSS has a rough surface, although it is embedded within the device (unless the substrate is removed), with a refractive index contrast, which increases light extraction and reduces internal reflection through the back-side interface.

With a rough surface, it is desirable to have minimal contact area to extract as much light as possible. To facilitate this, the contacts must be formed on a semiconductor layer with a high conductivity. P-type material in the III-nitrides is too resistive to form spreading layers, due to low hole mobility, and ohmic contacts to this material are of poor quality. On the other hand, contacts to n-type material are very good and the material has good conductivity, so n-type material may be used as a current spreading layer.

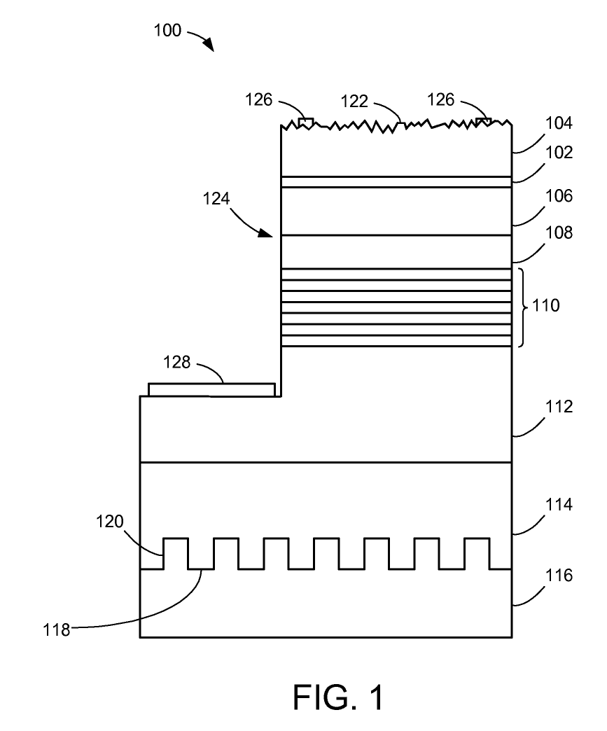

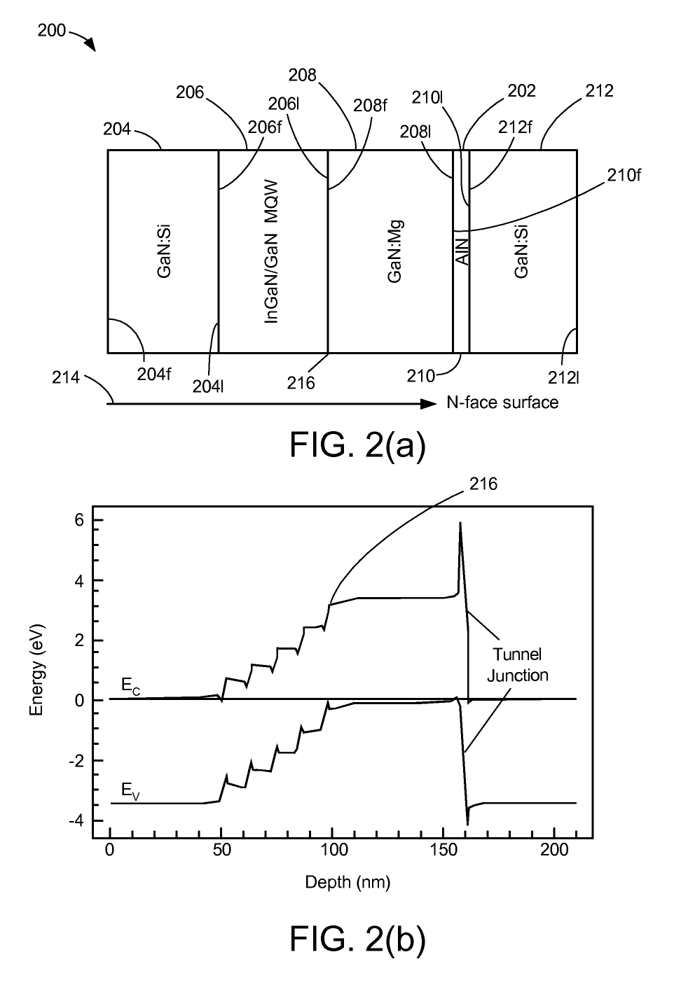

In the present invention, proposed device structures use a thin layer (<150 nm) of material that exhibits strong piezoelectric and/or spontaneous electrical polarization to provide an effective tunnel junction. In the nitride material system, any interface between differing AlInGaN alloys exhibits sheet charges that arise from the difference in net polarization between the layers. These layers have an inherent electric field that is induced by the polarization charges, that may be used to provide the dipole moment needed in a p/n junction, instead of using other space charge in the junction. In addition, the electric field provided by the polarization charges may be larger than can be provided by ionized donors and acceptors alone. Using this polarization-induced electric field, with or without the additional electric field provided by ionized donors and acceptors, the depletion region of the junction may be made small enough to enable efficient tunneling transport, even in large band-gap semiconductor systems, and may be used to fabricate an LED with all n-type contacts, as shown in FIGS. 1 and 2.

FIG. 1 is a schematic of a device 100 having a polarization-induced tunnel junction 102 comprised of strained c-plane N-face AlN, which is clad by GaN layers 104 and 106. Below the tunnel junction 102 is a standard LED structure with p-type (Mg doped) GaN 106, an AlGaN:Mg electron blocking layer 108, an InGaN/GaN multiple quantum well active region 110, and an n-type GaN layer (Si-doped) 112, all of which are grown on unintentionally doped (UID) N-face GaN buffers 114 on a PSS 116.

The PSS 116 may be formed by ion etching (which results in the backside roughness 118 of the GaN 112 grown on the pattern 120 of the PSS 116) and on the top-side of the Si doped GaN 104, roughness 122 can be formed by etching the wafer in a basic solution. Device fabrication follows with a mesa etch (to form mesa 124) by reactive ion etching and metal deposition for both n-type contacts 126, 128. The upper n-type contact 126 may be reflective, unannealed metal in a fine mesh pattern to ensure maximum efficiency.

Device Growth Structure and Band Diagram

FIG. 2(a) illustrates a schematic of a growth structure of an N-face LED 200 having a tunnel junction 202. The LED 200 includes an Si doped GaN layer 204, an InGaN/GaN multi quantum well active region 206, an Mg doped GaN layer 208, an AlN layer 210, and an Si doped GaN layer 212. The AlN layer 210 forms a tunnel junction 202 between the p-type GaN layer 208 and the n-type GaN layer 212. The arrow 214 in FIG. 2(a) shows the growth direction and the orientation of the N-face surface, and therefore indicates that the last grown surface 2041 of layer 204 is an N-face surface, the last grown surface 2061 of layer 206 is an N-face surface, the last grown surface 2081 of layer 208 is an N-face surface, the last grown surface 2101 of layer 210 is an N-face surface, and the last grown surface 2121 of layer 212 is an N-face surface. Consequently, the first grown surface 204f of layer 204 is a Ga-face surface, the first grown surface 206f of layer 206 is a group III atom-face surface, the first grown surface 208f of layer 208 is a Ga-face surface, and the first grown surface 210f of layer 210 is a group III-face surface, and the first grown surface 212f of layer 212 is a Ga-face surface. In conventional Ga [0001] growth, the surfaces 2041-2121 are Ga or group III atom faces and the surfaces 204f-212f are N-faces.

FIG. 2(b) is a band diagram of the structure shown in FIG. 2(a), as a function of depth through the layers 204-212, wherein depth=0 is the surface 204f of the n-type GaN layer 204. Specifically, the band diagram plots the conduction band energy E_{C} and the valence band energy E_{V}. The band diagram shows E_{C}˜0 in the n-type layers 204, 212, evidencing all n-type contact can be made to the LED 200 via the layers 204 and 212. The all n-type contacts are possible due to the polarization induced tunnel junction 202 whose energy is also shown in FIG. 2(b). The large gradient of E_{C} at the interface 216 between the active region 206 and the p-type layer 208 evidences a narrow depletion region. Finally, E_{V}˜0 in the thin p-type layer 208 evidences reduced series resistance for the device.

Possible Modifications

The following is a non-exhaustive list of possible modifications to the present invention described above:
a. Either the etched surface 122 or patterned sapphire 116 may be replaced with planar material.
b. A hole blocking layer, for example, Al(In)GaN:Si, may be added to prevent hole overflow out of the quantum wells.
c. The electron blocking layer 108 may be deleted.
d. The roughened top-side 122 may be deleted with or without the addition of fully reflecting n-type contacts 126.
e. The AlN tunnel junction 102 may be comprised of any other highly polar material that increases tunneling efficiency over a standard tunnel junction, with modifications in the stacking order of the p-type material 106 and n type material 104 to account for differences in polarization field direction.
f. The tunnel junction 102 may be a highly doped p/n junction.
g. The etched top-side 122 may be either a dry etch or wet etch, and can be random or ordered.
h. The substrate 116 may be any substrate that provides the needed index contrast with GaN or any III-nitride bulk film.
i. An epitaxial layer may be added to the surface 122 to further enhance light extraction by providing an intermediate index of refraction between the GaN and air or epoxy.
j. The layer compositions may be modified to include any AlInGaN alloy that provides a tunnel junction 102 and active region 110 with contact regions. For example, the electron blocking layer 108 may be comprised of AlInN that is lattice matched to GaN.
k. The LED 100 may involve flip-chip mounting and/or shaping to further increase extraction efficiency.
l. LEDs may have multiple active regions connected by tunnel junctions.
m. Multiple composition active regions may be used, for example, to emit different wavelengths.
n. The buffer 114 may be deleted if, for example, the device 100 is grown on lattice-matched material that has a roughened back-side 118. In this case, air provides the needed index contrast for the roughening to be effective. If free standing GaN is available, the buffer layer 114 can be removed as long as the roughened layer 118 is still intact.

Thus, the present invention discloses an optoelectronic device 100, such as an LED, comprising a p-type layer 106 on an n-type layer 112 (there may be additional layers between the p-type layer 106 and the n-type layer 112, such as an active region 110), a first n-type contact 126 for the p-type layer 106, one or more intermediate layers 104 and 102 between the first n-type contact 126 and the p-type layer 106 for transferring the device's 100 drive current (or in the case of a photovoltaic cell, transferring power supplied by the photovoltaic device) between the p-type layer 106 and first the n-type contact 126, and a second n-type contact 128 to the n-type layer 112). In this way, the one or more intermediate layers 102 may electrically connect an n-type contact 126 to a p-type region 106 to transfer sufficient charge to, for example, power light emission from the optoelectronic device 100.

Consequently, the optoelectronic device 100 may have only n-type contacts 126, 128 and no p-type contacts, wherein power is supplied via the first n-type contact 126 and the second n-type contact 128.

The intermediate layers 104, 102 may comprise, but are not limited to, a polarization-induced tunnel junction 102 between the p-type layer 106 and the n-type contact 126, which enables efficient tunneling transport between the p-type layer 106 and the n-type contact 126.

The intermediate layers 104, 102 may further comprise one or more n-type conductive layers 104 between the polarization induced tunnel junction 102 and the n-type contact 126. The one or more n-type conductive layers 104 may be an n-type current spreading layer 104 to compensate for minimal electrical contact created by the roughening 120.

Furthermore, a roughened n-type surface 122 may terminate the LED 100 to enhance light extraction, and the LED 100 may have a roughened back-side 118, which may be formed by a patterned substrate 116 of the LED 100 to provide embedded backside roughening. The LED 100 may be III-nitride based, and the roughened n-type surface 122 may be a roughened N-face.

Finally, FIG. 1 illustrates a method for fabricating an optoelectronic device, comprising fabricating only n-type contacts 126, 128 to the device 100 and roughening an n-type top surface 122 and a bottom surface 118 of the device 100. The roughening may be any surface texturing that enhances light extraction, including but not limited to, periodic and non periodic patterning.

Advantages and Improvements

The device of the present invention is superior to current designs in that the extraction efficiency is maximized by rough surfaces on two of the surfaces of the device. Roughening both faces of the device should double the efficiency gained by roughening a single face. Additionally, the upper surface has little metal on it due to the tunnel junction contacted p-type layer, so absorption losses are minimal compared to current designs that employ either semi-transparent contacts or mirrors with less-than-ideal reflectivity.

The purpose of the tunnel junction to allow all n-type electrical contact to the device. The tunnel junction allows surface roughening to be used more effectively. The top-side roughening can be and has been done without the n-type layer, but the n-type layer reduces the contact area because it is more conductive.

The present invention may also be used to fabricate devices other than LEDs; for example, it may be used to fabricate photovoltaic devices.

### References

The following references are incorporated by reference herein:

1. U.S. Pat. No. 6,847,057, issued Jan. 25, 2005, to Gardner et al., entitled “Semiconductor light emitting devices.”

2. U.S. Pat. No. 6,878,975, issued Apr. 12, 2005, to Mark R. Hueschen, entitled “Polarization Field Enhanced Tunnel Structures.”

Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching, without fundamentally deviating from the essence of the present invention. It is intended that the scope of the invention be limited not by this detailed description, but rather by the claims appended hereto.

What is claimed is:

1. An optoelectronic device, comprising:
(a) a p-type layer on an n-type layer;
(b) a first n-type contact for the p-type layer;
(c) one or more intermediate layers between the first n-type contact and the p-type layer for transferring the device's drive current between the p-type layer and the first n-type contact; and
(d) a second n-type contact for the n-type layer.

2. The optoelectronic device of claim 1, having only n-type contacts and no p-type contacts.

3. The optoelectronic device of claim 1, wherein:
(1) the optoelectronic device is a light emitting diode (LED);
(2) a roughened n-type surface terminates the LED to enhance light extraction;
(3) the LED's power is supplied via the first n-type contact and the second n-type contact.

4. The optoelectronic device of claim 3, wherein the LED has a roughened backside.

5. The optoelectronic device of claim 3, wherein the LED is fabricated on a patterned substrate to provide embedded backside roughening.

6. The optoelectronic device of claim 3, wherein the LED is III-nitride based and the roughened n-type surface is a roughened nitrogen-face (N-face).

7. The optoelectronic device of claim 6, wherein the LED is comprised of an epitaxial growth having an N-face orientation.

8. The optoelectronic device of claim 1, wherein the intermediate layers comprise:
(1) a polarization-induced tunnel junction between the p-type layer and the n-type contact, which enables efficient tunneling transport between the p-type layer and the n-type contact;
(2) one or more n-type conductive layers between the polarization-induced tunnel junction and the n-type contact.

9. The optoelectronic device of claim 8, wherein the one or more n-type conductive layers is an n-type current spreading layer to compensate for minimal electrical contact created by the roughening.

10. The optoelectronic device of claim 8, wherein the polarization-induced tunnel junction is aluminum nitride, and the n-type conductive layer and p-type layer are gallium nitride.

11. An optoelectronic device, comprising:
one or more intermediate layers for electrically connecting an n-type contact to a p-type region, wherein the intermediate layers transfer sufficient charge to power light emission from the optoelectronic device.

12. The optoelectronic device of claim 11, wherein the intermediate layers create a depletion region at a junction between the n-type contact and the p-type region, and the depletion region is sufficiently small to enable tunneling transport between the n-type contact and the p-type region.

13. The optoelectronic device of claim 11, wherein the intermediate layers comprise an n-type layer on a polarization induced tunnel junction.

14. A method for fabricating an optoelectronic device, comprising:
(a) fabricating only n-type contacts to the device; and
(b) roughening a top surface of the device, which is an n-type surface, and a bottom surface of the device.

15. The method of claim 14, wherein the optoelectronic device is a III-nitride nitrogen-face (N-face) light emitting diode (LED).

16. An AlInGaN-based optoelectronic device, comprising:
(a) a roughened nitrogen face (N-face) surface; and
(b) an surface opposite the roughened N-face surface that is also roughened;
(c) wherein the surfaces are roughened to enhance light extraction from the device.
